(19) United States
(12) Patent Application Publication
(10) Pub. No.: US 2025/0166968 A1
(43) Pub. Date: May 22, 2025

(54) PLASMA CHAMBER FOR WAFER ETCHING AND WAFER ETCHING METHOD USING PLASMA CHAMBER

(71) Applicant: Nam Hun KIM, Yeoju-si, Gyeonggi-do (KR)

(72) Inventor: Nam Hun KIM, Yeoju-si, Gyeonggi-do (KR)

(21) Appl. No.: 18/727,333

(22) PCT Filed: Nov. 9, 2022
(86) PCT No.: PCT/KR2022/017510

§ 371 Date: Jul. 8, 2024

(30) Foreign Application Priority Data
Jan. 26, 2022 (KR) 10-2022-0011797

(51) Int. Cl. H01J 37/32

(52) U.S. Cl. CPC H01J 37/32155; H01J 37/32724; H01J 37/32816; H01J 2237/3346

(57) ABSTRACT

The present invention relates to a plasma chamber for wafer etching and a wafer etching method using the plasma chamber, wherein the plasma chamber includes: a housing having a reaction space therein to etch a wafer through plasma; a base plate provided inside the housing and on which the wafer is seated; and a pressure adjusting unit for adjusting the pressure inside the housing, wherein the pressure adjusting unit adjusts the pressure inside the housing to 50-150 mTorr. The wafer etching method using the plasma chamber of the present invention comprises: a pressure adjustment step of adjusting the pressure inside the housing to 50-150 mTorr through the pressure adjusting unit; a source power adjustment step of adjusting a source power of the plasma source to 300-1000 W through the plasma source.

### TECHNICAL FIELD

The present invention relates to a plasma chamber for wafer etching and a wafer etching method using the plasma chamber, and more particularly, to a plasma chamber for wafer etching and a wafer etching method using the plasma chamber that can improve selectivity while maintaining a high etch rate.

### Background Art

In general, it is very important to achieve uniformity in processes for manufacturing semiconductors, and among manufacturing processes of semiconductors, the uniformity of semiconductors may be ensured or controlled during an etching process.

An etching process of a semiconductor may be carried out inside a plasma chamber. Plasma is formed in a reaction space in the plasma chamber, and the etching process of the semiconductor is performed using the plasma.

A plasma source for forming plasma is provided at an upper part of the plasma chamber, and representative examples of the plasma sources include capacitively coupled plasma (CCP) sources and inductively coupled plasma (ICP) sources.

A CCP source is a plasma source which uses an electric field and in which etching can generally be carried out at a slightly higher pressure than in an ICP source. A CCP source is known to have a low etch rate but excellent selectivity characteristics and process reproducibility.

However, a CCP source has plasma density non-uniformity characteristics in which a plasma density at the center of a wafer appears to be relatively higher than the plasma density at the edge of the wafer. In addition, a CCP source has a problem in that an overall plasma density is relatively low, and thus high RF power should be applied to increase the plasma density.

An ICP source is a plasma source which uses an induced magnetic field and has an advantage of having higher overall plasma density than a CCP source. An ICP source can increase an etch rate at a lower pressure than a CCP source, but it also has a problem in that the plasma density at the center of the wafer is relatively higher than the plasma density at the edge of the wafer, and the etch rate is high but selectivity is low and process reproducibility is low.

Conventional plasma sources such as an ICP source and a CCP source have a problem in that it is difficult to simultaneously increase the etch rate and the selectivity, and it has been recognized that there is a trade-off relationship between the etch rate and the selectivity.

### DISCLOSURE

### Technical Problem

The present invention is directed to solving the problems described above, and more particularly, to a plasma chamber for wafer etching and a wafer etching method using the plasma chamber that can improve selectivity while maintaining a high etch rate.

### Technical Solution

A plasma chamber for wafer etching according to an aspect of the present invention for solving the problems described above is a plasma chamber in which plasma is formed to etch a wafer, the plasma chamber including a housing having a reaction space therein to etch the wafer with plasma, a base plate provided inside the housing and on which the wafer is seated, and a pressure adjusting unit that adjusts a pressure inside the housing, in which the pressure adjusting unit adjusts the pressure inside the housing to 50 to 150 mTorr.

The plasma chamber for wafer etching according to the aspect of the present invention for solving the problems described above may further include a plasma source that is provided above the housing and forms plasma inside the housing, and source power of the plasma source may be in the range of 300 to 1000 W.

A driving frequency of the plasma source of the plasma chamber for wafer etching according to the aspect of the present invention for solving the problems described above may be formed to be equal to a collision frequency between particles within the housing.

Density of the plasma formed in the reaction space of the housing of the plasma chamber for wafer etching according to the aspect of the present invention for solving the problems described above may be in the range of 5E10 to 5E11 cm⁻³.

The plasma chamber for wafer etching according to the aspect of the present invention for solving the problems described above may further include a temperature adjusting unit that adjusts a temperature of the base plate, and the temperature adjusting unit may adjust the temperature of the base plate to 20 to 50° C.

The plasma chamber for wafer etching according to the aspect of the present invention for solving the problems described above may further include a bias RF source that is connected to the base plate and is able to apply a bias to the base plate, and bias power of the bias RF source may be in the range of 1000 to 3000 W.

The plasma formed in the reaction space of the housing of the plasma chamber for wafer etching according to the aspect of the present invention for solving the problems described above may contain ions and radicals, and the wafer may be etched by a synergy effect of the ions and the radicals.

The plasma formed in the reaction space of the housing of the plasma chamber for wafer etching according to the aspect of the present invention for solving the problems described above may contain electrons, and an electron energy relaxation length of the electrons may be smaller than a diameter of the housing.

A wafer etching method using a plasma chamber according to another aspect of the present invention for solving the problems described above is a wafer etching method for etching a wafer through the plasma chamber that includes a housing having a reaction space therein to etch the wafer with plasma, a base plate provided inside the housing and on which the wafer is seated, a pressure adjusting unit that adjusts a pressure inside the housing, and a plasma source that is provided above the housing and forms the plasma inside the housing, the wafer etching method including a pressure adjustment operation of adjusting the pressure inside the housing to 50 to 150 mTorr through the pressure adjusting unit and a source power adjustment operation of adjusting source power of the plasma source to 300 to 1000 W through the plasma source.

The wafer etching method using the plasma chamber according to another aspect of the present invention for solving the problems described above may further include a frequency adjustment operation of adjusting a driving frequency of the plasma source, and, in the frequency adjustment operation, the driving frequency of the plasma source may be adjusted so that the driving frequency of the plasma source is equal to a collision frequency between particles inside the housing.

In the wafer etching method using the plasma chamber according to another aspect of the present invention for solving the problems described above, density of the plasma formed in the reaction space of the housing may be in the range of 5E10 to 5E11 cm⁻³.

In the wafer etching method using the plasma chamber according to another aspect of the present invention for solving the problems described above, the plasma chamber may include a temperature adjusting unit that adjusts a temperature of the base plate, and the wafer etching method may further include a temperature adjustment operation of adjusting the temperature of the base plate to 20 to 50° C. through the temperature adjusting unit.

In the wafer etching method using the plasma chamber according to another aspect of the present invention for solving the problems described above, the plasma chamber may include a bias RF source that is connected to the base plate and is able to apply a bias to the base plate, and the wafer etching method may further include a bias power adjustment operation of adjusting bias power of the bias RF source to 1000 to 3000 W through the bias RF source.

In the wafer etching method using the plasma chamber according to another aspect of the present invention for solving the problems described above, the plasma formed in the reaction space of the housing may contain ions and radicals, and the wafer may be etched by a synergy effect of the ions and the radicals.

In the wafer etching method using the plasma chamber according to another aspect of the present invention for solving the problems described above, the plasma formed in the reaction space of the housing may contain electrons, and an electron energy relaxation length of the electrons may be smaller than a diameter of the housing.

### Advantageous Effects

The present invention relates to a plasma chamber for wafer etching and a wafer etching method using the plasma chamber and has an advantage of improving photoresistor (PR) selectivity while maintaining a high etch rate by forming a relatively higher pressure inside the chamber than in the conventional chamber.

In addition, the present invention has an advantage of achieving a high etch rate and high PR selectivity despite using lower power in the plasma source and bias RF source than in the conventional chamber.

### DESCRIPTION OF DRAWINGS

FIG. 1 is a diagram showing ions and radicals that etch a wafer.

FIG. 2 is a diagram showing a plasma chamber for wafer etching according to an embodiment of the present invention.

FIG. 3 is a diagram showing a wafer etching method using the plasma chamber according to an embodiment of the present invention.

FIG. 4 is a diagram showing a source power adjustment operation and a frequency adjustment operation according to an embodiment of the present invention.

FIG. 5 is a diagram showing a comparison of a plasma chamber according to an embodiment of the present invention, inductively coupled plasma (ICP), and capacitively coupled plasma (CCP), with respect to etch rate (ER), selectivity, chuck temperature (Chuck temp), source power (S/P), bias power (B/P), and pressure.

### MODES OF THE INVENTION

In this specification, the principles of the present invention are described and embodiments thereof are disclosed to clarify the scope of rights of the present invention and enable those skilled in the art to practice the present invention. The disclosed embodiments may be implemented in various forms.

Expressions such as “include” or “may include” that may be used in various embodiments of the present invention refer to the presence of the disclosed function, operation or component, and do not limit one or more additional functions, operations or components. It is to be understood that, in various embodiments of the present invention, terms such as “comprise” or “have” are intended to designate the presence of described features, numbers, steps, operations, components, parts, or combinations thereof, but do not preclude the presence or addition of one or more other features, numbers, steps, operations, components, parts, or combinations thereof.

When a component is described as being “coupled” or “connected” to another component, it should be understood that the component may be directly coupled or connected to another component, or other new components may exist between the component and another component. On the other hand, when a component is described as being “directly coupled” or “directly connected” to another component, it should be understood that there are no other components between the component and another component.

Terms such as “first,” “second,” etc. used in this specification may be used to describe various components, but the components should not be limited by the terms. The terms may be used for the purpose of distinguishing one component from another.

The present invention relates to a plasma chamber for wafer etching and a wafer etching method using the plasma chamber, and more particularly, to a plasma chamber for wafer etching and a wafer etching method using the plasma chamber that can improve selectivity while maintaining a high etch rate.

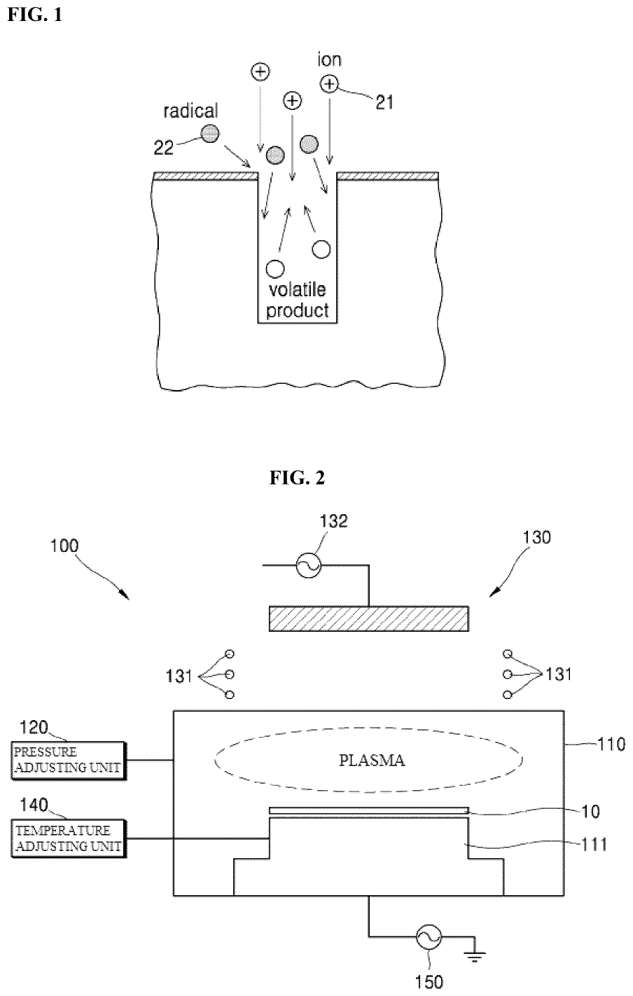

Referring to FIG. 1, plasma consists mainly of electrons, ions 21, and radicals 22. In a conventional method of etching a wafer with plasma, dominant species are formed as either ions or radicals during a plasma etching process.

Specifically, in a conventional method of etching a wafer with plasma, radicals are mainly used for etching metals, while ions are mainly used for etching oxides.

In a plasma chamber for wafer etching and a wafer etching method using the plasma chamber according to an embodiment of the present invention, the dominant species is formed not by one between ions and radicals during the plasma etching process, but ions 21 and radicals 22 can be used simultaneously.

That is, in the plasma chamber for wafer etching and the wafer etching method using the plasma chamber according to the embodiment of the present invention, rather than causing an ion-dominated reaction or a radical-dominated reaction during the plasma etching process, a process area where ions 21 and radicals 22 act together to exhibit a synergy effect during the plasma etching process is used.

More specifically, in the plasma chamber for wafer etching and the wafer etching method using the plasma chamber according to the embodiment of the present invention, selectivity can be improved while maintaining a high etch rate through the synergy effect generated by resonance between ions and radicals while using ions and radicals simultaneously.

The plasma chamber for wafer etching and the wafer etching method using the plasma chamber according to the embodiment of the present invention may be a reduction on and a solution to the problems of using a conventional inductively coupled plasma (ICP) source.

The plasma chamber for wafer etching and the wafer etching method using the plasma chamber according to the embodiment of the present invention may be those that employ a synergistic resonance ICP (SRICP) that uses the synergy effect generated by resonance may be employed.

In the plasma chamber for wafer etching and the wafer etching method using the plasma chamber according to the embodiment of the present invention, the conditions of the plasma chamber can be adjusted to use ions and radicals simultaneously.

In the plasma chamber for wafer etching and the wafer etching method using the plasma chamber according to the embodiment of the present invention, the pressure inside the chamber, the temperature of the chuck, the source power of the plasma source, the driving frequency of the plasma source, the plasma density inside the chamber, the bias power of the bias RF source, etc. can be adjusted, and in the plasma chamber for wafer etching and the wafer etching method using the plasma chamber according to the embodiment of the present invention, ions and radicals can be used simultaneously by changing the above conditions in the plasma chamber.

Hereinafter, exemplary embodiments of the present invention will be described in detail with reference to the accompanying drawings.

Referring to FIG. 2, a plasma chamber 100 for wafer etching according to an embodiment of the present invention includes a housing 110, a base plate 111, and a pressure adjusting unit 120.

The housing 110 has a reaction space therein to etch a wafer 10 with plasma. The housing 110 may be an outer wall of the plasma chamber 100 for wafer etching according to the embodiment of the present invention, and has a space therein. When the wafer 10 is loaded into the housing 110, the wafer 10 may be etched by plasma formed inside the housing 110.

The base plate 111 is provided inside the housing 110, and the wafer 10 is seated thereon. The base plate 111 may be a plate provided inside the housing 110 such that the wafer 10 is seated on the base plate 111.

More specifically, the base plate 111 may be a wafer chuck that supports the wafer 10 and allows the wafer 10 to be seated, and when the wafer 10 is seated on the base plate 111, etching may be carried out on the wafer 10.

The pressure adjusting unit 120 adjusts a pressure inside the housing 110. The pressure adjusting unit 120 may be a pressure adjusting unit that adjusts the pressure inside the housing 110, and the pressure adjusting unit 120 may be a device that includes various components as long as the components can adjust the pressure inside the housing 110.

According to the embodiment of the present invention, the pressure adjusting unit 120 can adjust the pressure inside the housing 110 to be in the range of 50 to 150 mTorr. As described above, in the plasma chamber for wafer etching according to the embodiment of the present invention, ions 21 and radicals 22 can be used simultaneously.

In the plasma chamber for wafer etching according to the embodiment of the present invention, the pressure inside the housing 110 can be adjusted to be in the range of 50 to 150 mTorr through the pressure adjusting unit 120 in order to simultaneously use ions 21 and radicals 22.

When using ions 21 and radicals 22 simultaneously, when the pressure inside the housing 110 is less than 50 mTorr, there is a risk that the etch rate will be reduced. In contrast, when the pressure inside the housing 110 is greater than 150 mTorr, there may be too much reaction between particles, making the reaction time shorter, and the etch rate may actually decrease accordingly.

Therefore, in the plasma chamber for wafer etching according to the embodiment of the present invention, the pressure inside the housing 110 is preferably adjusted to 50 to 150 mTorr through the pressure adjusting unit 120.

The plasma chamber for wafer etching according to the embodiment of the present invention may further include a plasma source 130 provided on an upper part of the housing 110 and forming plasma inside the housing 110.

The plasma source 130 is capable of forming plasma and may include a coil 131 and an RF power generator 132. According to the embodiment of the present invention, source power of the plasma source 130 can be adjusted to 300 to 1000 W.

When the source power formed by the plasma source 130 is less than 300 W, the etch rate decreases, and thus the source power formed by the plasma source 130 is preferably greater than 300 W.

As described above, in the plasma chamber for wafer etching according to the embodiment of the present invention, the pressure inside the housing 110 is adjusted to 50 to 150 mTorr through the pressure adjusting unit 120, and accordingly, the pressure inside the housing 110 may be higher than that of a conventional plasma chamber.

When the source power formed by the plasma source 130 is greater than 1000 W, the plasma density may become too high due to a relatively high internal pressure of the housing 110. When the plasma density becomes too high, there may be too much reaction between particles, making the reaction time shorter, and the etch rate may actually decrease accordingly.

Therefore, in the plasma chamber for wafer etching according to the embodiment of the present invention, the source power of the plasma source 130 is preferably adjusted to 300 to 1000 W.

In the plasma source 130 of the plasma chamber for wafer etching according to the embodiment of the present invention, a driving frequency of the plasma source 130 is preferably formed to be equal to a collision frequency between particles inside the housing 110.

As described above, in the plasma chamber for wafer etching according to the embodiment of the present invention, selectivity can be improved while maintaining a high etch rate through the synergy effect generated by resonance between ions and radicals while using ions and radicals simultaneously.

In the plasma chamber for wafer etching according to the embodiment of the present invention, in order to induce resonance between ions and radicals, the driving frequency of the plasma source 130 is preferably formed to be equal to the collision frequency between particles inside the housing 110.

The collision frequency between particles inside the housing 110 may be determined as a product of the number of particles per unit volume and a rate constant for a collision reaction. In the plasma source 130 according to the embodiment of the present invention, data on the collision frequency is analyzed first, and on the basis of the analysis result, the driving frequency of the plasma source 130 can be adjusted to be equal to the collision frequency between particles inside the housing 110.

The plasma chamber for wafer etching according to the embodiment of the present may include a collision frequency analyzing unit that analyzes the collision frequency between particles occurring inside the housing 110, and the plasma source 130 can receive data from the collision frequency analyzing unit and adjust the driving frequency of the plasma source 130.

According to the embodiment of the present invention, the driving frequency of the plasma source 130 can be adjusted through the RF power generator 132 provided in the plasma source 130.

According to the embodiment of the present invention, the density of the plasma formed in the reaction space of the housing 110 is preferably in the range of 5E10 to 5E11 cm⁻³.

When the density of the plasma formed in the reaction space of the housing 110 is less than 5E10 cm⁻³, a target etch rate cannot be obtained.

In contrast, when the density of the plasma formed in the reaction space of the housing 110 is greater than 5E11 cm⁻³, ions 21 and radicals 22 are separated from each other, which may adversely affect selectivity.

That is, in the plasma chamber for wafer etching according to the embodiment of the present invention, the density of the plasma formed in the reaction space of the housing 110 is formed to be in the range of 5E10 to 5E11 cm⁻³ in order to improve the etch rate selectivity while improving the etch rate by simultaneously using ions 21 and radicals 22.

The density of the plasma formed in the reaction space of the housing 110 according to the embodiment of the present invention may be adjusted by the plasma source 130. Specifically, through the plasma source 130, a plasma density suitable for simultaneous use of ions 21 and radicals 22 can be formed inside the housing 110.

Referring to FIG. 2, the plasma chamber 100 for wafer etching according to the embodiment of the present invention may further include a temperature adjusting unit 140 that adjusts the temperature of the base plate 111.

The temperature adjusting unit 140 may be a temperature adjusting device that is connected to the base plate 111 and can adjust the temperature of the base plate 111. The temperature adjusting unit 140 may include various components as long as it can adjust the temperature of the base plate 111.

By adjusting the temperature of the base plate 111 through the temperature adjusting unit 140, the temperature of the wafer 10 seated on the base plate 111 can be adjusted.

According to the embodiment of the present invention, the temperature adjusting unit 140 preferably adjusts the temperature of the base plate 111 to 20 to 50° C. While ions 21 are independent of the temperature of the wafer 10, radicals 22 may react sensitively to the temperature of the wafer 10.

Therefore, when the temperature of the base plate 111 falls below 20° C., the temperature of the wafer 10 decreases, which may limit the activity of radicals. In addition, when the temperature of the base plate 111 is higher than 50° C., there is a risk of burning occurring.

The wafer 10 according to the embodiment of the present invention is preferably maintained at a temperature in the range of room temperature (20 to 50° C.) in order to simultaneously react with ions 21 and radicals 22. To this end, the temperature of the base plate 111 is preferably adjusted to 20 to 50° C. through the temperature adjusting unit 140.

Referring to FIG. 2, the plasma chamber 100 for wafer etching according to the embodiment of the present invention may further include a bias RF source 150 that is connected to the base plate 111 and may apply a bias to the base plate 111.

The bias RF source 150 may apply a bias to the base plate 111, thereby applying a bias to the plasma during the etch process.

According to the embodiment of the present invention, a bias power of the bias RF source 150 is preferably adjusted to 1000 to 3000 W. The bias power directly affects ions 21.

When the bias power of the bias RF source 150 is less than 1000 W, the activity of ions 21 is restricted and the activity of radicals 22 becomes dominant, and accordingly, the synergy effect of ions 21 and radicals 22 cannot be expected.

In contrast, when the bias power of the bias RF source 150 is greater than 3000 W, the activity of ions becomes dominant, and accordingly, the synergy effect of ions 21 and radicals 22 cannot be expected.

As a result, in the chamber 100 according to the embodiment of the present invention, the bias power of the bias RF source 150 should be adjusted to 1000 to 3000 W in order to derive the synergy effect of ions 21 and radicals 22.

According to the embodiment of the present invention, the plasma formed in the reaction space of the housing 110 contains ions 21 and radicals 22, and the wafer 10 may be etched by the synergy effect of ions 21 and radicals 22.

In addition, the plasma formed in the reaction space of the housing contains electrons, and an electron energy relaxation length (EERL) of the electrons may be smaller than a diameter of the housing.

In the plasma chamber 100 for wafer etching according to the embodiment of the present invention, an etching process can be carried out in a process area of local electron kinetics. A conventional etching process was carried out in a process area of nonlocal electron kinetics, where the EERL is always greater than the diameter of a process chamber.

However, in the plasma chamber 100 for wafer etching according to the embodiment of the present invention, the etching process can be carried out in the process area of local electron kinetics where the EERL is smaller than the diameter of the process chamber (diameter of the housing 110).

Through this, in the plasma chamber 100 for wafer etching according to the embodiment of the present invention, the plasma density at edges of the housing 110 can be made to be higher than that at the center of the housing 110, and the etch rate at the edges of the housing 110 may be higher than that at the center of the housing 110.

In the conventional etching process, a problem where the etching is weakly performed at the edge of the wafer (low edge yield problem) may occur, whereas, in the plasma chamber 100 for wafer etching according the embodiment of the present invention, the etch rate is made to be higher at the edges of the housing 110 than at the center of the housing 110, and thereby the above problems can be prevented from occurring.

In addition, in the conventional etching process, in order to solve the problem where the etching is weakly performed at the edge of the wafer (low edge yield problem), independent RF power was applied thereto, or a heater or a lift device to prevent corrosion of an edge ring was used.

However, in the plasma chamber 100 for wafer etching according to the embodiment of the present invention, by making the etch rate at the edges of the housing 110 higher than at the center of the housing 110, a separate device need not be used, and accordingly, the plasma chamber 100 has an advantage of reducing manufacturing costs and improving yield.

A wafer etching method using a plasma chamber according to an embodiment of the present invention relates to a method of etching the wafer 10 through the plasma chamber 100 for wafer etching according to the embodiment of the present invention described above.

Since the plasma chamber 100 for wafer etching according to the embodiment of the present invention has been described in detail in the above description, detailed description of the plasma chamber 100 for wafer etching according to the embodiment of the present invention will be omitted below.

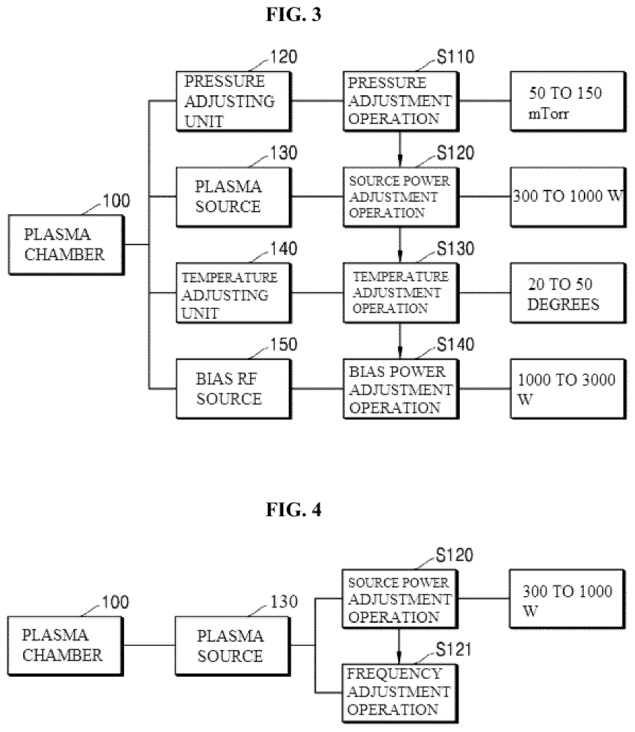

Referring to FIG. 3, the wafer etching method using the plasma chamber according to the embodiment of the present invention includes a pressure adjustment operation S110 and a source power adjustment operation S120.

The pressure adjustment operation S110 is an operation of adjusting the pressure inside the housing 110 to 50 to 150 m Torr through the pressure adjusting unit 120.

According to the embodiment of the present invention, when using ions 21 and radicals 22 simultaneously, when the pressure inside the housing 110 is less than 50 mTorr, there is a risk that the etch rate will be reduced. In contrast, when the pressure inside the housing 110 is greater than 150 mTorr, there may be too much reaction between particles, making the reaction time shorter, and the etch rate may actually decrease accordingly.

Therefore, in the pressure adjustment operation S110, the pressure inside the housing 110 is preferably adjusted to 50 to 150 mTorr through the pressure adjusting unit 120.

The source power adjustment operation S120 is an operation of adjusting the source power of the plasma source 130 to 300 to 1000 W through the plasma source 130.

When the source power formed by the plasma source 130 is less than 300 W, the etch rate decreases, and thus the source power formed by the plasma source 130 is preferably greater than 300 W.

As described above, since the pressure inside the housing 110 is adjusted to 50 to 150 mTorr through the pressure adjusting unit 120 in the pressure adjustment operation S110, the pressure inside the housing 110 may be higher than that of a conventional plasma chamber.

When the source power formed by the plasma source 130 is greater than 1000 W, the plasma density may become too high due to the relatively high internal pressure of the housing 110. When the plasma density becomes too high, there may be too much reaction between particles, making the reaction time shorter, and the etch rate may actually decrease accordingly.

Therefore, in the source power adjustment operation S120, the source power of the plasma source 130 is preferably adjusted to 300 to 1000 W.

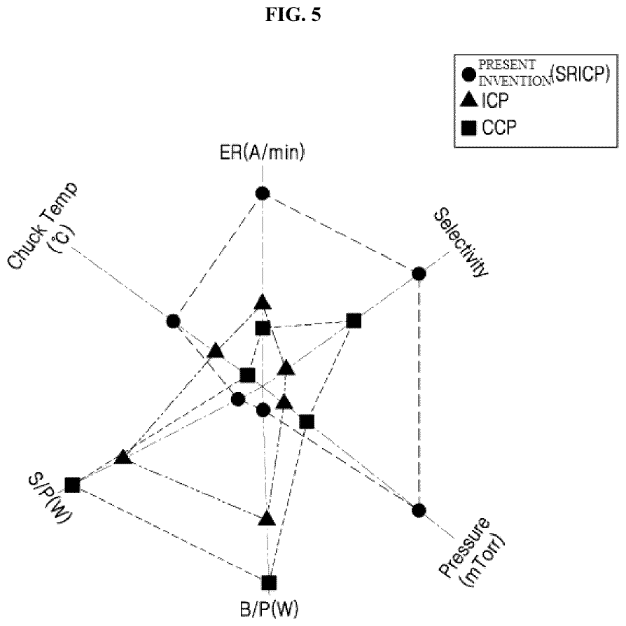

Referring to FIG. 4, the wafer etching method using the plasma chamber according to an embodiment of the present invention may include a frequency adjustment operation S121 of adjusting a driving frequency of the plasma source 130.

In the frequency adjustment operation S121, the driving frequency of the plasma source 130 can be adjusted so that the driving frequency of the plasma source 130 is equal to a collision frequency between particles inside the housing 110

As described above, in the plasma chamber for wafer etching according to the embodiment of the present invention, selectivity can be improved while maintaining a high etch rate through the synergy effect generated by resonance between ions and radicals while using ions and radicals simultaneously.

According to the embodiment of the present invention, in order to induce resonance between ions and radicals in the plasma chamber, the driving frequency of the plasma source 130 is preferably formed to be equal to the collision frequency between particles inside the housing 110.

The collision frequency between particles inside the housing 110 may be determined as a product of the number of particles per unit volume and a rate constant for a collision reaction. In the plasma source 130 according to the embodiment of the present invention, data on the collision frequency is analyzed first, and on the basis of the analysis result, the driving frequency of the plasma source 130 can be adjusted to be equal to the collision frequency between particles inside the housing 110.

The plasma chamber for wafer etching according to the embodiment of the present may include a collision frequency analyzing unit that analyzes the collision frequency between particles occurring inside the housing 110,

The frequency adjustment operation S121 according to the embodiment of the present invention is an operation of receiving data from the collision frequency analyzing unit and adjusting the driving frequency of the plasma source 130 to be equal to the collision frequency between particles inside the housing 110.

According to the embodiment of the present invention, the density of the plasma formed in the reaction space of the housing 110 is preferably in the range of 5E10 to 5E11 cm⁻³.

When the density of the plasma formed in the reaction space of the housing 110 is less than 5E10 cm⁻³, a target etch rate cannot be obtained.

In contrast, when the density of the plasma formed in the reaction space of the housing 110 is greater than 5E11 cm⁻³, ions 21 and radicals 22 are separated from each other, which may adversely affect selectivity.

That is, in the plasma chamber for wafer etching according to the embodiment of the present invention, the density of the plasma formed in the reaction space of the housing 110 is formed to be in the range of 5E10 to 5E11 cm⁻³ in order to improve selectivity while improving the etch rate by simultaneously using ions 21 and radicals 22.

The density of the plasma formed in the reaction space of the housing 110 according to the embodiment of the present invention can be adjusted in the source power adjustment operation S120. In the source power adjustment operation S120, the source power of the plasma source 130 can be adjusted to form the density of the plasma in the reaction space of the housing 110 to be in the range of 5E10 to 5E11 cm⁻³.

Referring to FIG. 3, the wafer etching method using the plasma chamber according to the embodiment of the present invention may further include a temperature adjustment operation S130 of adjusting the temperature of the base plate 111 to 20 to 50° C. through the temperature adjusting unit 140.

The temperature adjusting unit 140 may be a temperature adjusting device that is connected to the base plate 111 and can adjust the temperature of the base plate 111. By adjusting the temperature of the base plate 111 through the temperature adjusting unit 140, the temperature of the wafer 10 seated on the base plate 111 can be adjusted.

According to the embodiment of the present invention, in the temperature adjustment operation S130, the temperature of the base plate 111 is preferably adjusted to 20 to 50° C. While ions 21 are independent of the temperature of the wafer 10, radicals 22 may react sensitively to the temperature of the wafer 10.

Therefore, when the temperature of the base plate 111 falls below 20° C., the temperature of the wafer 10 decreases, which may limit the activity of radicals. In addition, when the temperature of the base plate 111 is higher than 50° C., there is a risk of burning occurring.

The wafer 10 according to the embodiment of the present invention is preferably maintained at a temperature in the range of room temperature (20 to 50° C.) in order to simultaneously react with ions 21 and radicals 22. To this end, in the temperature adjustment operation S130, the temperature of the base plate 111 can be adjusted to 20 to 50° C.

Referring to FIG. 3, the wafer etching method using the plasma chamber according to the embodiment of the present invention may further include a bias power adjustment operation S140 of adjusting a bias power of the bias RF source 150 to 1000 to 3000 W through the bias RF source 150.

The bias RF source 150 may apply a bias to the base plate 111, thereby applying a bias to the plasma during the etch process.

The bias power may directly affect ions 21. When the bias power of the bias RF source 150 is less than 1000 W, the activity of ions 21 is restricted and the activity of radicals 22 becomes dominant, and accordingly, the synergy effect of ions 21 and radicals 22 cannot be expected.

In contrast, when the bias power of the bias RF source 150 is greater than 3000 W, the activity of ions becomes dominant, and accordingly, the synergy effect of ions 21 and radicals 22 cannot be expected.

Therefore, in order to derive the synergy effect of ions 21 and radicals 22, the bias power of the bias RF source 150 can be adjusted to 1000 to 3000 W.

The pressure adjustment operation S110, the source power adjustment operation S120, the frequency adjustment operation S121, the temperature adjustment operation S130, and the bias power adjustment operation S140 of the wafer etching method using the plasma chamber according to the embodiment of the present invention do not need to be performed sequentially, and can be performed in any order.

In addition, the pressure adjustment operation S110, the source power adjustment operation S120, the frequency adjustment operation S121, the temperature adjustment operation S130, and the bias power adjustment operation S140 of the wafer etching method using the plasma chamber according to the embodiment of the present invention may be carried out simultaneously.

In the plasma chamber for wafer etching and the wafer etching method using the plasma chamber according to the embodiment of the present invention, the pressure inside the housing 110 can be adjusted through the pressure adjusting unit 120, the source power can be adjusted through the plasma source 130, the temperature of the base plate 111 can be adjusted through the temperature adjusting unit 140, and the bias power can be adjusted through the bias RF source 150 as described above.

In the plasma chamber for wafer etching and the wafer etching method using the plasma chamber according to the embodiment of the present invention, ions 21 and radicals 22 are used simultaneously by adjusting the pressure inside the housing 110, the source power, the temperature of the wafer, and the temperature of the bias power to generate a synergy effect to improve selectivity while maintaining a high etch rate, and thereby selectivity can be improved while maintaining a high etch rate.

According to the embodiment of the present invention, the plasma formed in the reaction space of the housing 110 contains ions 21 and radicals 22, and the wafer 10 may be etched by the synergy effect of ions 21 and radicals 22.

In addition, according to the embodiment of the present invention, the plasma formed in the reaction space of the housing contains electrons, and the EERL of the electrons may be smaller than the diameter of the housing.

In the plasma chamber 100 for wafer etching according to the embodiment of the present invention, unlike the conventional etching method in which the etching process is carried out in the process area of nonlocal electron kinetics where the EERL is greater than the diameter of the process chamber, the etching process may be performed in the process area of local electron kinetics where the EERL is smaller than the diameter of the process chamber (diameter of the housing 110).

Through this, in the plasma chamber 100 for wafer etching according to the embodiment of the present invention, the plasma density at edges of the housing 110 can be made higher than that at the center of the housing 110, and the etch rate at the edges of the housing 110 may be higher than that at the center of the housing 110.

In the plasma chamber 100 for wafer etching according to the embodiment of the present invention, by making the etch rate at the edges of the housing higher than at the center of the housing, the problem that etching is weakly performed at the edge of the wafer (low edge yield problem) may be solved, and there is an advantage in that a separate device for solving the above problem need not be used.

In FIG. 5, ER (A/min) indicates an etch rate, S/P (W) indicates a source, B/P (W) indicates bias power, Chuck temp (° C.) indicates a temperature of the base plate 111, ICP indicates inductively coupled plasma, and CCP indicates capacitively coupled plasma.

Referring to FIG. 5, in the plasma chamber for wafer etching and the wafer etching method using the plasma chamber according to the embodiment of the present invention, photoresistor (PR) selectivity can be improved while maintaining a high etch rate by forming a higher pressure than the conventional CCP and ICP.

In addition, in the plasma chamber for wafer etching and the wafer etching method using the plasma chamber according to the embodiment of the present invention, a high etch rate and high PR selectivity can be achieved despite using lower power than the conventional CCP and ICP.

The plasma chamber for wafer etching according to the embodiment of the present invention may include a control unit that controls the operation of the pressure adjusting unit 120, the plasma source 130, the RF power generator 132, the temperature adjusting unit 140, and the bias RF source 150.

According to the embodiment of the present invention, the operation of the pressure adjusting unit 120, the plasma source 130, the RF power generator 132, the temperature adjusting unit 140, and the bias RF source 150 is controlled through the control unit, and thereby conditions in which ions 21 and radicals 22 can be used simultaneously can be formed.

In addition, the pressure adjustment operation S110, the source power adjustment operation S120, the frequency adjustment operation S121, the temperature adjustment operation S130, and the bias power adjustment operation S140 of the wafer etching method using the plasma chamber according to the embodiment of the present invention may be carried out while being controlled through the control unit.

The plasma chamber for wafer etching and the wafer etching method using the plasma chamber according to the embodiment of the present invention described above have the following effects.

The plasma chamber for wafer etching and the wafer etching method using the plasma chamber according to the embodiment of the present invention have an advantage of improving PR selectivity while maintaining a high etch rate by forming the pressure inside the chamber to a relatively higher pressure than in the conventional chamber.

In addition, the present invention has an advantage of achieving a high etch rate and high PR selectivity despite using lower power in the plasma source and bias RF source than in the conventional chamber.

In the plasma chamber for wafer etching and the wafer etching method using the plasma chamber according to the embodiment of the present invention, the etching process can be carried out in the pressure range (50 to 150 mTorr) where local electron kinetics is applied, and in this case, the etch rate at the edge of the wafer can be higher than that at the center thereof.

Through this, the plasma chamber for wafer etching and the wafer etching method using the plasma chamber according to the embodiment of the present invention has an advantage of preventing uniformity from being degraded at the edge of the wafer.

The plasma chamber for wafer etching and the wafer etching method using the plasma chamber according to the embodiment of the present invention are suitable for a high aspect ratio contact (HARC) etching process, and high etch rate and high selectivity can be achieved at low power in other processes as well.

The plasma chamber for wafer etching and the wafer etching method using the plasma chamber according to the embodiment of the present invention have been described focusing on the etching process, but are not limited thereto. The plasma chamber for wafer etching and the wafer etching method using the plasma chamber according to the embodiment of the present invention can be applied to processes such as deposition, ashing, PR stripping, and doping in addition to the etching process.

The plasma chamber for wafer etching and the wafer etching method using the plasma chamber according to the embodiment of the present invention can be applied to an etching process or a deposition process that requires a high etch rate, but are not limited thereto, and can of course be applied to several processes that require high etch rate or improved selectivity at the same time with low power.

The plasma chamber for wafer etching and the wafer etching method using the plasma chamber according to the embodiment of the present invention can be used by improving an ICP, but are not limited thereto, and can be used for various types of plasma.

The present invention has been described above with reference to an embodiment shown in the drawings, but this is merely illustrative and those skilled in the art will understand that various modifications and variations of the embodiment are possible therefrom. Therefore, the true scope of technical protection of the present invention should be determined by the technical idea of the attached claims.

1. A plasma chamber in which plasma is formed for etching a wafer, the plasma chamber comprising:
a housing having a reaction space therein to etch a wafer through plasma;
a base plate provided inside the housing and on which the wafer is seated; and
a pressure adjusting unit that adjusts a pressure inside the housing,
wherein the pressure adjusting unit adjusts the pressure inside the housing to 50 to 150 mTorr.

2. The plasma chamber of claim 1, further comprising a plasma source that is provided above the housing and forms plasma inside the housing,
wherein source power of the plasma source is in a range of 300 to 1000 W.

3. The plasma chamber of claim 2, wherein a driving frequency of the plasma source is formed to be equal to a collision frequency between particles within the housing.

4. The plasma chamber of claim 1, wherein density of the plasma formed in the reaction space of the housing is in a range of 5E10 to 5E11 cm⁻³.

5. The plasma chamber of claim 1, further comprising a temperature adjusting unit that adjusts a temperature of the base plate,
wherein the temperature adjusting unit adjusts the temperature of the base plate to 20 to 50° C.

6. The plasma chamber of claim 1, further comprising a bias RF source that is connected to the base plate and applies a bias to the base plate,
wherein bias power of the bias RF source is in a range of 1000 to 3000 W.

7. The plasma chamber of claim 1, wherein:
the plasma formed in the reaction space of the housing contains ions and radicals; and
the wafer is etched by a synergy effect of the ions and the radicals.

8. The plasma chamber of claim 1, wherein:
the plasma formed in the reaction space of the housing contains electrons; and
an electron energy relaxation length of the electrons is smaller than a diameter of the housing.

9. A wafer etching method for etching a wafer through a plasma chamber that includes a housing having a reaction space therein to etch the wafer with plasma, a base plate provided inside the housing and on which the wafer is seated, a pressure adjusting unit that adjusts a pressure inside the housing, and a plasma source that is provided above the housing and forms the plasma inside the housing, the wafer etching method comprising:
a pressure adjustment operation of adjusting the pressure inside the housing to 50 to 150 mTorr through the pressure adjusting unit; and
a source power adjustment operation of adjusting source power of the plasma source to 300 to 1000 W through the plasma source.

10. The wafer etching method of claim 9, further comprising a frequency adjustment operation of adjusting a driving frequency of the plasma source,
wherein, in the frequency adjustment operation, the driving frequency of the plasma source is adjusted so that the driving frequency of the plasma source is equal to a collision frequency between particles inside the housing.

11. The wafer etching method of claim 9, wherein density of the plasma formed in the reaction space of the housing is in a range of 5E10 to 5E11 cm⁻³.

12. The wafer etching method of claim 9, wherein:
the plasma chamber includes a temperature adjusting unit that adjusts a temperature of the base plate; and
the wafer etching method further comprises a temperature adjustment operation of adjusting the temperature of the base plate to 20 to 50° C. through the temperature adjusting unit.

13. The wafer etching method of claim 9, wherein:
the plasma chamber includes a bias RF source that is connected to the base plate and applies a bias to the base plate; and
the wafer etching method further comprises a bias power adjustment operation of adjusting bias power of the bias RF source to 1000 to 3000 W through the bias RF source.

14. The wafer etching method of claim 9, wherein:
the plasma formed in the reaction space of the housing contains ions and radicals; and
the wafer is etched by a synergy effect of the ions and the radicals.

15. The wafer etching method of claim 9, wherein:
the plasma formed in the reaction space of the housing contains electrons; and
an electron energy relaxation length of the electrons is smaller than a diameter of the housing.
